(19) United States
(12) Patent Application Publication
(10) Pub. No.: US 2023/0047606 A1
(43) Pub. Date: Feb. 16, 2023

(54) DISPLAY PANEL AND DISPLAY APPARATUS

(71) Applicant: SeeYA Optronics Co., Ltd., Shanghai (CN)

(72) Inventor: Zhongshou HUANG, Shanghai (CN)

(21) Appl. No.: 17/489,432

(22) Filed: Sep. 29, 2021

(30) Foreign Application Priority Data
Aug. 16, 2021 (CN) 202110937813.3

(51) Int. Cl. H01L 27/32; H01L 51/52

(52) U.S. Cl. CPC H01L 27/322; H01L 27/3246; H01L 27/3262; H01L 27/3265; H01L 27/3276; H01L 51/5253

(57) ABSTRACT

A display panel and a display apparatus are provided. The display panel comprises a substrate of crystalline silicon, a display area and a non-display area on the substrate; a plurality of organic light-emitting elements with white light-emitting overlapping the display area, wherein the organic light-emitting element comprises a first electrode layer, a light-emitting function layer, and a second electrode layer that are sequentially stacked in a direction away from the substrate; wherein the first electrode layer comprises a plurality of independent first electrodes, each second electrode comprises at least one striped opening, and vertical projections of the striped openings on the display area overlap at least 75% of vertical projections of the scan lines on the display area.

### CROSS-REFERENCE TO RELATED APPLICATIONS

This application is based upon and claims priority to Chinese Patent Application No. 202110937813.3, filed on Aug. 16, 2021, the entire contents of which are incorporated herein by reference.

### TECHNICAL FIELD

The present disclosure relates to display technology, and more particularly to a display panel and a display apparatus.

### BACKGROUND

With technology development and market share expansion of wearable display apparatuses for augmented reality (AR) and virtual reality (VR) using organic light-emitting diode (OLED) displays, the technical requirements for an OLED display panel used for the AR and VR applications are also getting higher. As the display resolution has been expanded to an ultra-high resolution of 5000 ppi (pixel per inch), more vivid colors, higher brightness, as well as 60 Hz or higher frame rate are also desired. In attempting to pursue these unprecedented ultra-high display performances, similar to the development history of integrated circuit chips, technology developers have encountered bottlenecks and face challenges, such as, high power consumption, high heat generation and large noise crosstalk. As a pixel density increases significantly, a distance between pixels and between different layers shrinks, and additional power loss and degradation of image signal caused by various parasitic effects such as leakage current and parasitic capacitance become more serious. Moreover, these phenomena are often interrelated. For example, a parasitic capacitance causes noise crosstalk, and also causes additional power loss due to the charging/discharging process of the parasitic capacitance.

FIG. 1 is a schematic cross-sectional view of a display panel in the related art, this kind of display panel uses a combination of a white light-emitting layer and a color resistance layer on each pixel to achieve a color image. Except the color filter layer on each pixel, there is no need for an evaporation mask or a lithography process for the white light-emitting layer and the uppermost cathode metal, as the result, the OLED layers and the cathode electrode extend continuously on the entire display panel. As shown in FIG. 1, the display panel is an OLED display fabricated on a silicon wafer, is therefore called a silicon-based OLED. Similar to ordinary CMOS (Complementary Metal Oxide Semiconductor) devices, a heavily-doped diffusion layer of the source 02S and a heavily-doped diffusion layer of the drain 02D of the transistor are prepared on the silicon substrate 01, and the source electrode 05S and the drain electrode 05D produced later are in ohmic contact with the diffusion layer of the source 02S and the diffusion layer of the drain electrode 02D through via-holes on oxide layer 03. On the oxide layer 03, a polysilicon gate is fabricated to control the conduction status of the transistor. A prepared pixel array is then covered with an insulating layer 06, and then power lines 07P, scan lines 07A, etc. At the same time, through a via hole, a source electrode 05S of the transistor in OLED is connected to an anode 021 of OLED through a metal pillar 09in the via hole, the terminals of each pixel that need to be controlled or supplied with voltage source from the outside are connected to the corresponding bus lines (not shown in FIG. 1). In some OLED devices, the thicknesses of the anodes of different color pixels are varied for better color purity through the effect of light wave resonance (not shown in FIG. 1). The anodes 021 of the pixels are separated by a pixel definition layer 030. The pixel definition layer 030 also plays a role in avoiding a large leakage current or in a worst case break down between the anode and the cathode caused by strong fringe field at the edges of the anode.

On the anode array and the pixel definition layer, a plurality of functional layers of the OLED and the cathode electrode 025 are consecutively deposited in a vacuum coating equipment. For convenience and without losing generality, FIG. 1 here only illustrates the simplest three-layer structure of OLED, which includes a hole injection transport layer 022 in contact with the anode 021, strictly speaking, includes a hole injection layer and a hole transport layer thereon. An electron injection transport layer 024 is in contact with the cathode electrode uppermost of the OLED stacks, and between the hole injection transport layer 022 and the electron injection transport layer 024 is a light-emitting layer 023. There is usually a planarization layer 031 on the cathode electrode 025. The planarization layer 031 is used to eliminate the unevenness of the surface caused by the anodes 021 and the pixel definition layer 030, so that a subsequent color filter layer can be evenly coated. Above the planarization layer 031 are color filter layers of different colors, such as a red filter layer 032R and a green filter layer 032G, and a black layer for absorbing light and then reducing color mixing, the black layer is usually referred to a black matrix 033 (BM), as shown in FIG. 1.

Due to the high sensitivity of the OLED to oxygen and moisture, as well as the difficulty of preparing high-resolution masks, the multiple functional layers of OLED cover the surface of display completely rather than discretely. For example, the cathode electrode uppermost usually continuously covers the entire surface of display. However, as shown in FIG. 1, between the cathode electrode 025 and the underlying metal bus line for driving each pixel, through the gap between two adjacent anodes, there is an overlapping area between the vertical projection of the cathode electrode 025 and that of the scan line 07A, which causes a parasitic capacitance 051. In the same manner, the cathode electrode 025 covering the entire surface of OLED display panel will also generate related parasitic capacitances with other metal bus lines, such as a power line 07P that provides OLED drive current or other control bus lines. Due to periodical pulse voltage passing through the control bus lines, or any voltage fluctuations due to the current variations caused by refreshing of the display image, the charging and discharging of the above parasitic capacitance occur, which will inevitably introduce additional power consumption and delay dynamic response of the display panel.

Limited to the two-dimensional cross-sectional view of FIG. 1, other possible parasitic capacitances are not shown in FIG. 1 and these parasitic capacitances are schematically illustrated by an equivalent circuit diagram of a pixel in FIG. 2. FIG. 2 is a schematical OLED pixel equivalent circuit diagram. The circuit includes a driving transistor T1 and a writing transistor T2. The writing transistor T2 is only used as a switch, which writes a new data voltage signal V_{Data} to the gate of the driving transistor periodically (e.g., for a certain time period such as for every frame period), wherein a voltage signal represents the brightness of the pixel. The writing transistor T2 is turned on or off by scan lines. In order to keep the voltage signal against leakage current within one frame, a storage capacitor Cst is added in each pixel. The source of the driving transistor T2 is connected to the anode of the OLED, and the drain is connected to the external power supply line biased by V_{DD}. The external power provides the current required for OLED to emit light through the driving transistor of each pixel. The cathode of the OLED is applied with a cathode voltage V_{C}, which is equally applied to the cathode of each OLED in pixel.

The capacitors with reference signs 051, 052, 053, and 054 are the parasitic capacitances between the cathode electrode of the OLED and the four driving bus lines around the pixel. Whenever there is a voltage change across a parasitic capacitance, there will be charging and discharging currents passing through the parasitic capacitance, which affects the image quality and power consumption. In particular, the parasitic capacitances 051 and 052 between the cathode and the two scan lines will induce significant charge and discharge currents synchronizing with the scan voltage pulse in each frame period. Even for the case of the data line that provides data voltage and the power line that presumably provides a stable voltage, due to data voltage refreshing, the current on the data line and the power line will change accordingly. Because of the resistance along the power line, OLED current inevitably produces a voltage drop along the power line, any changes in the OLED current will induces voltage fluctuation on the power line and therefore induce parasitic currents through the parasitic capacitances.

In addition, as the resolution of OLED display increases, the effective light-emitting area in each pixel is reduced in a certain proportion. However, limited by photolithography process capability, all parasitic effects are reduced much slower than the effective light-emitting area of the pixel. The above-mentioned physical effects lead to an inevitable trend of performance degradation, that is, as the resolution increases, or the pixel density increases, the parasitic effects degrade the image quality and increase the power consumption. For AR and VR glasses that are worn on the head or supported by two ears or the nose, it will be unrealistic to be equipped with a large lithium battery.

In addition to the above-mentioned drawback of parasitic capacitance in a conventional OLED display panel, leakage current of OLED that does not contribute to light output may occur, hereinafter which is referred as edge parasitic leakage current. FIG. 3 schematically illustrates the mechanism of the parasitic leakage current in an enlarged view of a pixel definition layer and an edge of an anode in FIG. 1. The reference signs of various parts in FIG. 3 can refer to those of FIG. 1.

Referring to FIG. 3, since the hole injection layer 022 is in contact with the anode 021 and the hole transport layer 022 deposited on the anode 021 has higher conductivity, under the forces of diffusion and drift driven by transverse electric field, part of the holes will laterally diffuse to the sidewalls of the pixel definition layer 030 or even the upper part of the pixel definition layer 030, and then move toward the upper cathode electrode 025 to form a current. When the field strength is large enough, this part of the carriers may undergo a quantum transition and recombination, and generate light. Unfortunately, the black matrix 033 located above the planarization layer 031 almost blocks this part of the light completely. In other words, this part of the current I₂ is different from the OLED current I₁ that can really contribute to the emitted light, and it is a useless leakage current, which leads to a loss of power consumption.

Therefore, eliminating or reducing the above-mentioned parasitic effects significantly is the primary objective of the present disclosure.

### SUMMARY

In a first aspect of the present disclosure, a display panel is provided, including: a substrate of crystalline silicon, a display area and a non-display area on the substrate; a pixel circuit layer located in the display area on one side of the substrate, wherein, the pixel circuit layer includes a plurality of the scan lines, a plurality of data lines and a plurality of power lines; a pixel definition layer located on a side of the pixel circuit layer away from the substrate, wherein, the pixel definition layer includes a plurality of openings and barriers circumferentially surrounding each opening; a plurality of organic light-emitting elements with white light-emitting covering the display area, wherein, the organic light-emitting element includes a first electrode layer, a light-emitting function layer, and a second electrode layer that are sequentially stacked in a direction away from the substrate; wherein, the first electrode layer includes a plurality of independent first electrodes, the second electrode layer includes a plurality of second electrodes, each second electrode includes at least one striped opening, and vertical projections on the display area of the striped openings cover at least 75% of vertical projections on the display area of the scan lines.

In a second aspect of the present disclosure, a display apparatus is provided, including the display panel according to the above first aspect of the present disclosure.

It should be readily understood that both the foregoing general description and the following detailed description are exemplary and explanatory only, and are not intended as a limitation to the scope of the present disclosure.

### BRIEF DESCRIPTION OF THE DRAWINGS

The foregoing and other features, and advantages of the invention are apparent from the following detailed description taken in conjunction with the accompanying drawings in which:

FIG. 1 is a schematic cross-sectional view of a display panel in the related art;

FIG. 2 is a circuit diagram of an equivalent circuit of an OLED pixel illustrated in FIG. 1;

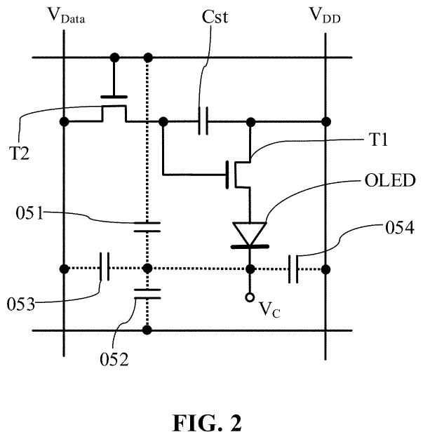

FIG. 3 is an enlarged view of a pixel definition layer and an edge of an anode in FIG. 1;

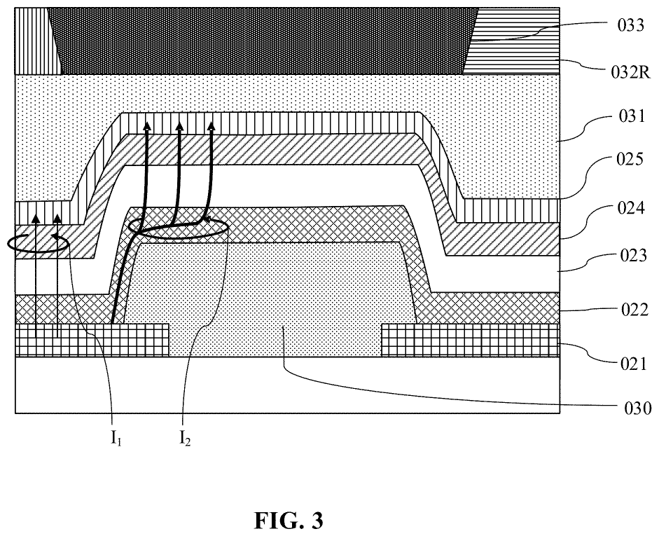

FIG. 4 is a schematic top view of a part of a display panel according to an embodiment of the present disclosure;

FIG. 5 is a schematic cross-sectional view along a section line AA′ in FIG. 4;

FIG. 6 is a schematic cross-sectional view along a section line AA′ in FIG. 4, illustrating another embodiment of a display panel according to the present disclosure;

FIG. 7 is another schematic cross-sectional view along a section line AA′ in FIG. 4, illustrating another embodiment of a display panel according to the present disclosure;

FIG. 8 is a schematic top view of a part of a display panel according to another embodiment of the present disclosure;

FIG. 9 is a schematic top view of a part of a display panel according to another embodiment of the present disclosure;

FIG. 10 is a schematic top view of a part of a display panel according to another embodiment of the present disclosure; and

FIG. 11 is a schematic cross-sectional view of a display panel according to the embodiment in FIG. 10.

### DETAILED DESCRIPTION

In the following, embodiments of the present disclosure will be described in detail with reference to the figures. It should be understood that, the embodiments described hereinafter are only used for explaining the present disclosure, and should not be understood to limit the present disclosure. Besides, for describing the embodiments more clearly, the figures only show some aspects, instead of every aspect, of the present disclosure.

The “first”, “second” and similar words used in the present disclosure do not denote any order, quantity or importance, but are only used to distinguish different components. “comprise”, “include” and other similar words mean that the elements or objects appearing before these words, the elements or objects listed after these words, and their equivalents, but other elements or objects are not excluded. Similar words such as “connected” are not limited to physical or mechanical connections, but may include electrical connections, whether direct or indirect. “up”, “down”, etc. are only used to indicate the relative position relationship. When the absolute position of the described object changes, the relative position relationship may also change accordingly.

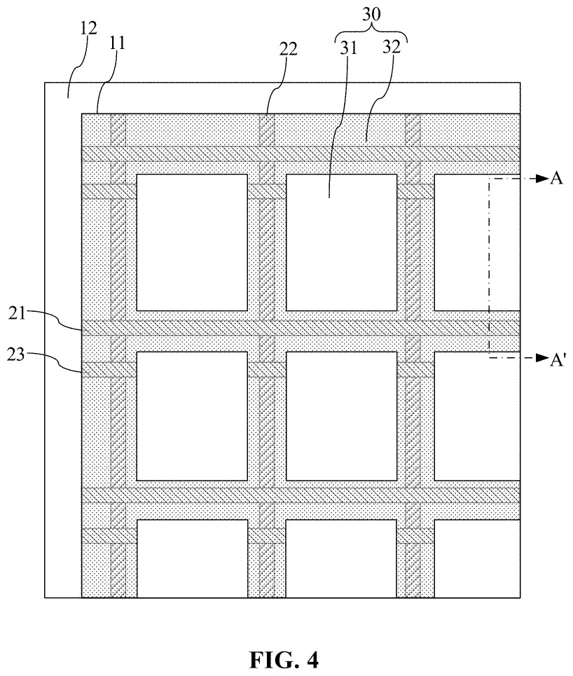

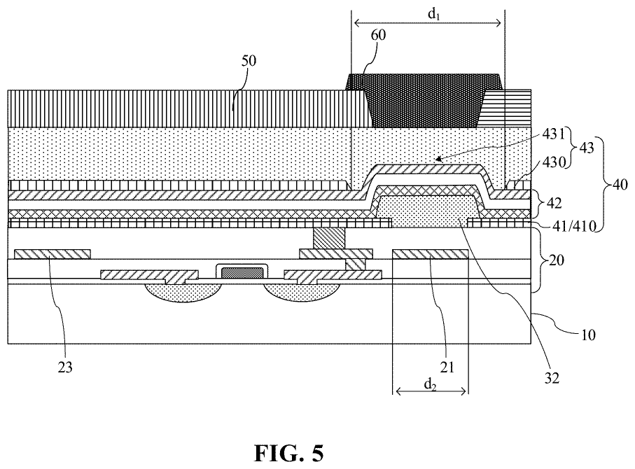

In order to solve the above-mentioned technical problems, embodiments in the present disclosure provide a display panel, which can be applied to AR or VR apparatuses. For the sake of convenient explanation, descriptions of substantially the same parts as those of the display panel described above will be omitted or not described in detail. FIG. 4 is a schematic top view of a part of a display panel according to an embodiment of the present disclosure, and FIG. 5 is a schematic cross-sectional view along a section line AA′ in FIG. 4. As shown in FIGS. 4 and 5, a display panel provided by this embodiment includes: a substrate 10 of crystalline silicon, a display area 11 and a non-display area 12 on the substrate 10; a pixel circuit layer 20 located in the display area 11 on one side of the substrate 10, wherein the pixel circuit layer 20 includes a plurality of the scan lines 21, a plurality of data lines 22 and a plurality of power lines 23; a pixel definition layer 30 located on a side of the pixel circuit layer 20 away from the substrate 10, wherein the pixel definition layer 30 includes a plurality of openings 31 and barriers 32 circumferentially surrounding each opening; a plurality of organic light-emitting elements 40 with white light-emitting covering the display area 11, wherein the organic light-emitting element 40 includes a first electrode layer 41, a light-emitting function layer 42, and a second electrode layer 43 that are sequentially stacked in a direction away from the substrate 10. That is, the first electrode layer 41 is more adjacent to the substrate 10. For the clarity of illustration, the organic light-emitting element 40 is not shown in FIG. 4. In some embodiments, the first electrode layer 41 includes a plurality of independent first electrodes 410, the second electrode layer 43 includes a plurality of second electrodes 430 and a plurality of striped openings 431. Each striped opening 431 partially or entirely overlaps with the scan line 21 in the direction of projection on the display area 11. In some embodiments, each second electrode 430 includes at least one striped opening 431 or adjacent to at least one elongated openings. In some embodiments, the vertical projections on the display area 11 of the striped openings 431 overlap at least 75% of vertical projections on the display area 11 of the scan lines 21. The above technical solution can eliminate most of the parasitic capacitance caused by the overlap between the scan lines and the second electrodes.

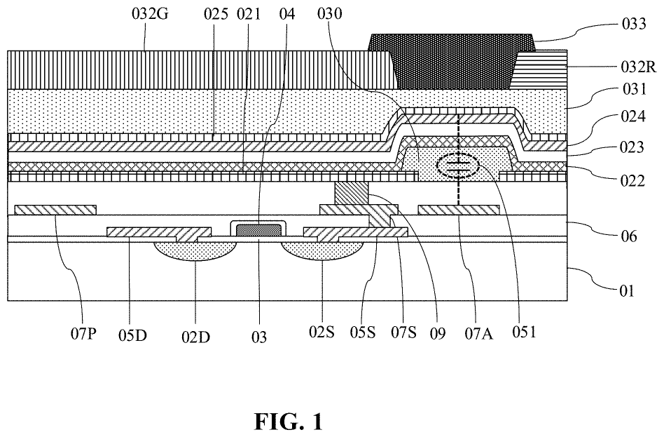

In the above embodiment, the substrate 10 is a crystalline silicon substrate, and a transistor structure can be directly formed on the substrate 10 to form a silicon-based display panel through a process such as doping, which is beneficial to increase the pixel density of the display panel. The transistor and other specific structures may be the same as or similar to the structures in FIG. 1, and will not be described in detail here. Two adjacent scan lines 21 and two adjacent data lines 22 in the display area 11 surround an organic light-emitting element 40. The scan lines 21 can extend in the row direction, and the data lines 22 can extend in the column direction of the array of organic light-emitting elements 40. The power lines 23 can be parallel to the scan lines 21, the data lines 22, or both. FIG. 4 exemplarily shows that the power line 23 and the scan line 21 are parallel, but this is not a limitation to the scope of the present disclosure. In this embodiment, all the organic light-emitting elements 40 emit white light, so that the vapor deposition of the organic light-emitting elements can be completed by one time. In order to generate different monochromatic light, the display panel further includes a color resistance layer 50 and a light-shielding layer 60, the color resistance layer 50 and the light-shielding layer 60 are located on a side of the organic light-emitting element away from the substrate 10, wherein the color resistance layer 50 covers the first electrode layer 41, and the light-shielding layer 60 covers the barriers 32. The color resistance layer 50 can include red color resistances, green color resistances and blue color resistances, so as to realize color display. In other embodiments, organic light-emitting elements with red light-emitting, organic light-emitting elements with green light-emitting and organic light-emitting elements with blue light-emitting can also be fabricated separately. In this case, a color resistance layer may or may not be provided. The color resistance layer can weaken the reflection of the external light in the display panel, for example, weaken the reflection of the external light of the second electrode layer.

In this embodiment, the first electrode 410 is the anode of the organic light-emitting element 40, the second electrode 430 is the cathode of the organic light-emitting element 40, and the structure of the light-emitting function layer 42 is the same as that in FIG. 1. The striped opening 431 located directly above and corresponding to the scan line 21 decreases the overlapping area of the second electrode 430 and the scan line 21 such that the parasitic capacitance that would be formed between the second electrode 430 and the scan line 21 can be reduced. A plurality of striped openings 431 may be cut out on the second electrode layer 43. In some embodiments, the opening may be a striped opening. In some embodiments, a plurality of striped openings 431 are cut out on the second electrode layer 43 directly above the scan line 21 to reduce the parasitic capacitance between them. In one exemplary embodiment shown in FIG. 5, a width d₁ of the striped opening 431 is greater than a width d₂ of the scan line 21. In some embodiments, the width d₁ of the striped opening 431 is equal to the width d₂ of the scan line 21. In some embodiments, the striped opening 431 is configured such that the area of total opening is at least 75% of the scan lines in the display area. In this way, although the striped openings 431 may not cover all the scan lines 21 in the display area, they overlap at least 75% of the scan lines 21 in the display area. Under the striped opening 431 of the second electrode 430, the conductivity of the light-emitting functional layer 42 is much lower than that of the second electrode 430 (e.g., at least several orders of magnitude lower), and thus the leakage current of the light-emitting functional layer 42 at the barrier 32 can be suppressed to a minimum or to be at a negligible level. Further, although the light-shielding layer 60 doped with carbon powder generally has certain conductivity, its conductivity is much lower than that of the cathode. At the same time, because the planarization layer increases the vertical distance of the pixel array, the parasitic capacitance between the scan line 21 and the light shielding layer 60 can also be ignored. In addition, since a vertical distance between the light-shielding layer and the driving bus line is increased due to the existence of the planarization layer, the parasitic capacitance between the scan line 21 and the light-shielding layer 60 also can be ignored.

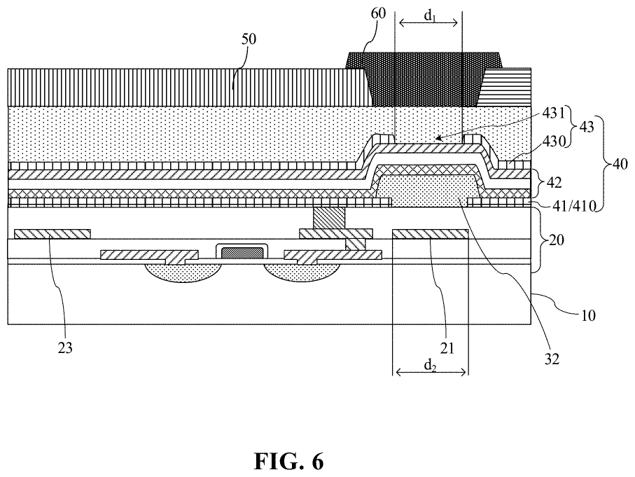

In other embodiments, if the layers of OLED on the sidewalls of the barriers are very thin, or there are surface defects or fractures, etc., in order to avoid pollution of OLED on the sidewalls of the barriers or prevent damage from the etching process during a process of patterning the second electrodes, the width of the striped opening may be configured to be smaller than the width of the barrier. FIG. 6 is a schematic cross-sectional view along a section line AA′ in FIG. 4, illustrating another embodiment of the display panel. For the sake of convenient explanation, descriptions of substantially the same parts as those of the display panel described above will be omitted or not described in detail. Exemplarily, as shown in FIG. 6, the width d₁ of the striped opening 431 is configured to be smaller than the width d₂ of the scan line 21. In specific implementation, these aspects of reducing parasitic capacitance and avoiding edge defects of the organic light-emitting elements can be balanced to improve the performance of the display panel.

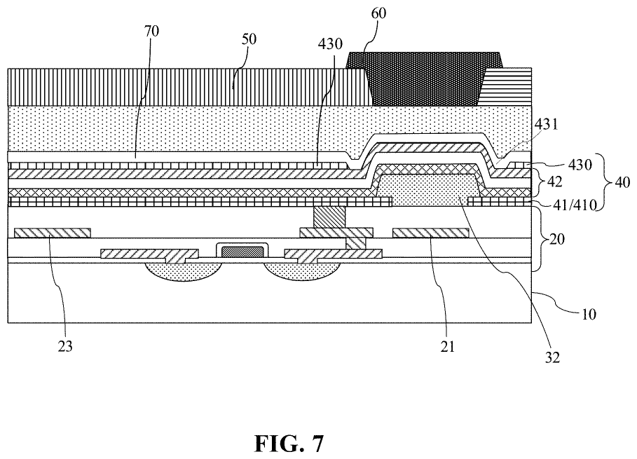

FIG. 7 is a schematic cross-sectional view along a section line AA′ in FIG. 4, illustrating another embodiment of a display panel of the present disclosure. For the sake of convenient explanation, descriptions of substantially the same parts as those of the display panel described above will be omitted or not described in detail. Referring to FIG. 7, the light-emitting function layer 42 covers the first electrode 410 above the striped opening 431 and the barrier 32, the display panel also includes a protective insulating layer 70 disposed on a side of the second electrode layer 43 away from the substrate 10. The protective insulating layer 70 covers the second electrode 430 and the light-emitting function layer 42 located above the barrier 32.

By reasonably selecting the material and filming process of the protective insulating layer 70, its adverse effects on the layers of OLED can be neglected and the protective insulating layer 70 maintains a high degree of transparency to the visible light emitted by the OLED. In the subsequent coating and baking process of the organic planarization layer, the influence of the varied layers in the pixel definition layer will be significantly reduced due to the covering of a protective insulating layer, thereby maintaining the stability of the layers of OLED.

In another embodiment, in the process of patterning the second electrode layer 43 or evaporating the protective insulating layer 70, the surface or body of the layers of OLED on the pixel definition layer or on the side wall of the retaining wall structure 32 can be inactivated, so that this part of the OLED no longer conducts electricity and/or emits light. Such inactivation treatment may include plasma treatment, etc. In another embodiment, the striped opening 431 can be obtained by etching part or all of the layers on the pixel definition layer by a method such as chemical or reactive ion etching (RIE). Since the film layer etched away by chemical or physical methods is located above the pixel definition layer and it has a certain distance from the film layer of the pixel light-emitting area, its adverse effects can be neglected.

In some embodiments, the second electrode may include a plurality of branch electrodes, and the branch electrodes can be strip-shaped. A vertical projection on the display area of each branch electrode is located between the vertical projections on the display area of two adjacent scan lines.

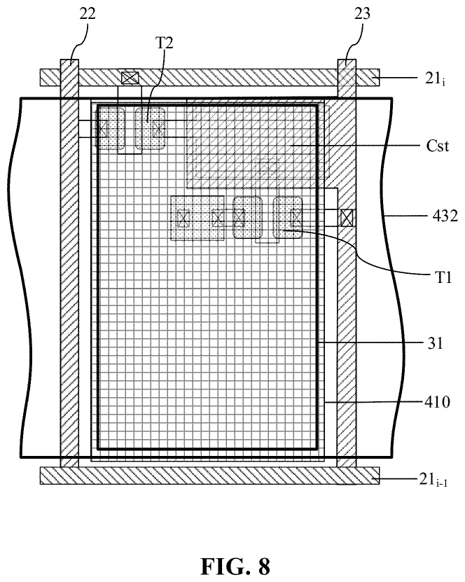

FIG. 8 is a schematic top view of a part of a display panel according to an embodiment of the present disclosure. FIG. 8 shows only one branch electrode 432 (i.e., the second electrode), where control pulse voltage of the (i)-th scan line 21ᵢ is VAᵢ, control pulse voltage of the (i−1)-th scan line 21ᵢ₋₁ is VAᵢ₋₁, and so on. The scan pulse voltage VA, controls the on and off statuses of the transistor T2. FIG. 8 also shows the data line 22 and the power line 23. The voltage signal V_{Data} is applied to the data line 22, and the constant power supply V_{DD} is applied to the power line 23. Also illustrated in FIG. 8 is the transistor T1 that drives OLED and the storage capacitor Cst that stores the voltage signal. In the illustrated embodiment, one branch electrodes 432 is spaced apart from another to expose the scan line 21. For example, the edge of the branch electrode 432 is spaced apart from the edge of another branch electrode and the space is configured to expose the scan line 21 to reduce or eliminate the overlapping areas between the second electrode and the scan line 21. FIG. 8 also schematically shows the edge of the opening 31 of the pixel definition layer 30 and the first electrode (anode) 410 below the opening. In order to reduce the negative effect caused by the fringe electric field of the anode 410, the edge of the anode 410 is protected by the pixel definition layer 30, so the opening of the pixel definition layer 30 is slightly smaller than that of the anode 410.

In the embodiment of FIG. 8, in order to eliminate the parasitic capacitance between the second electrode 430 and the scan line 21, as shown in FIG. 8, a part of the second electrode 430 originally covering the scan line has been etched away (that is the second electrode is configured as branched electrode 432), thereby, the parasitic capacitance between the second electrode 430 and the scan line 21 can be reduced or eliminated. In order to maintain the external power supply to the second electrode, the branch electrodes can be connected to each other in the non-display area. For example, no striped opening is provided in the non-display area, and then one or several bus lines are used to connect the branch electrodes to an external power supply. In another embodiment (not shown), in every few pixels, a second electrode connection bridge is disposed between adjacent branch electrodes to make the adjacent branch electrodes form a parallel connection, thereby improving conduction uniformity and voltage uniformity of the second electrodes in the entire display area.

In order to further reduce the parasitic effect between the second electrode and the pixel circuit layer below, photolithography is used to remove the branch electrodes above the transistors and/or storage capacitors, that is, vertical projections on the substrate of a branch electrode does not overlap with that of a transistor and/or a storage capacitor. In a specific implementation, vertical projections on the substrate of the first electrodes may be partially overlapped with those of the transistors and/or the storage capacitors, for example, the overlapping area is less than or equal to 10% of the area of the pixel circuit layer.

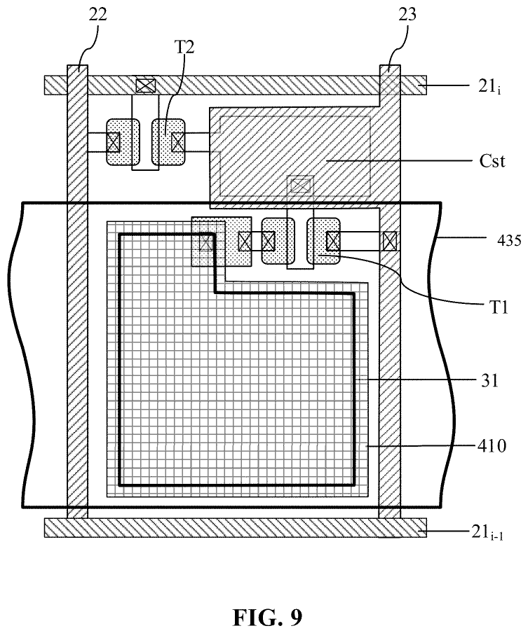

FIG. 9 is a schematic top view of a part of a display panel according to an embodiment of the present disclosure. The pixel circuit layer of the embodiment in FIG. 9 includes a plurality of driving transistors T1, a plurality of writing transistors T2 and a plurality of storage capacitors Cst. FIG. 9 schematically illustrates that the second electrode 435 does not overlap with the writing transistor T2 and the storage capacitor Cst. In one embodiment, vertical projections on the substrate of first electrodes 410 do not overlap with those of the transistors T1, T2 and/or a storage capacitor Cst, such that overlap area between vertical projections of the first electrodes 410 and those of the transistors, and the overlap area between vertical projections of the first electrodes 410 and those of storage capacitors are minimum or almost reduced to zero, thereby substantially eliminating the capacitive coupling between the anode and the power line 23, the anode and the scan line 21, the anode and the drive transistor, as well as the anode and the writing transistor. The above structure improves the signal-to-noise ratio. It should be understood that, in other embodiments, the pixel circuit may include more transistors, such as a pixel circuit with a threshold compensation function. In specific implementation, it can be designed according to actual requirement.

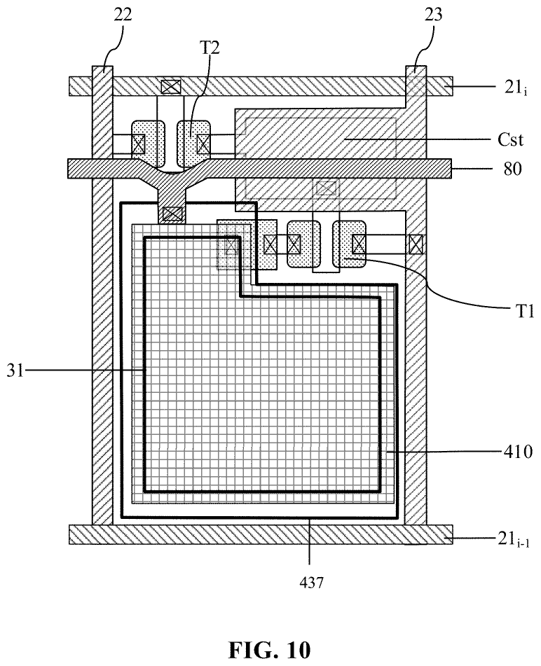

FIG. 10 is a schematic top view of a part of display panel according to an embodiment of the present disclosure. Unlike the previous described embodiments, in this embodiment, the second electrode 437 is configured to be an independent block for each pixel, so that there is no overlapping between the second electrodes 437 and the scan line 21, between the second electrode 437 and the data line 22, between the second electrode 437 and the power line 23.

The above structure minimizes parasitic capacitances. In other embodiments, second electrodes 437 may be partially overlapped with transistors and/or storage capacitors, for example, the overlapping area is configured to be less than or equal to 10% of the area of the pixel circuit layer.

Continuing with FIG. 10, the second electrode 437 may be configured based on the layout of the transistors and/or storage capacitors. In the illustrated embodiments, the second electrode 437 has a rectangular shape with a cut-out corner corresponding to the transistors and/or storage capacitors to expose the transistors and/or storage capacitors. The opening may be configured to have a shape similar to that of the second electrode 437.

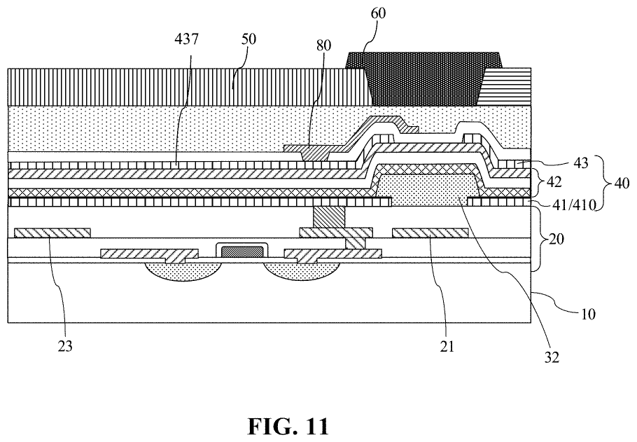

FIG. 11 is a schematic cross-sectional view of a display panel according to the embodiment illustrated in FIG. 10. The display panel in the embodiment of FIGS. 10 and 11 further includes a plurality of first metal bus lines 80. The first metal bus lines 80 are located on a side of the second electrode layer 43 away from the substrate 10, and one first metal bus line 80 can connect all independent second electrodes 437 of the pixels between two adjacent scan line rows.

Since the first metal bus lines 80 do not need to be light-transparent, they can be thick enough to reduce the total resistance of the second electrodes (usually the cathodes of the OLED). Due to its sufficiently small resistance, the width of the first metal bus line 80 at the intersection of longitudinal data line and power line can be reduced, at least can be much smaller than the width of one pixel, thereby greatly reducing parasitic capacitances between the cathode and the data line, or the cathode and the power line.

In order to improve the efficiency of electron injection into OLEDs, metals with lower work functions, such as Al, Ag, Mg: Ag alloys or LiF—Al composite layers, are usually used as the cathodes. Due to the low light transmittance of these materials, for example, the visible light transmittance of silver with a thickness of 10 nm is only about 70%, the cathode usually needs to be as thin as possible. However, a cathode with reduced thickness will have increased overall resistance accordingly. Therefore, it is a great challenge to balance the conductivity and light transmittance of the cathode. If the first metal bus line of this embodiment is used, the conductivity of the cathode is no longer a key factor to be considered, the cathode can be very thin, which greatly increases the light output of the OLED. Even if the cathodes overlap the driving bus lines, such as the power lines, the data lines or the scan lines, which brings a certain parasitic capacitance, the method of this embodiment can also be used to greatly reduce the resistance between the cathodes and the external power supply, and then to partially offset the negative effects caused by the RC delay of charging/discharging of parasitic capacitance. In order to minimize the reflection of the first metal bus lines to external light, the first metal bus lines can be made of low-reflective metals, such as Cr.

In the schematic cross-sectional view of FIG. 11, the part of the cathode electrode above the pixel definition layer is removed. It should be pointed out that even if the cathode electrode is not etched or patterned, that is, the cathode electrode covers the entire display area, and first metal bus lines still can be used to greatly reduce the resistances of the cathodes. In this way, whenever a row of pixels or a picture is refreshed with different gray-scale voltages, the external cathode power supply can provide the required currents to a large number of OLEDs at a faster speed and a more uniform voltage. Not only the dynamic response characteristics of the display apparatus, but also the voltage drop of the cathode is reduced, which is the so-called IR-DROP of the cathode.

It should be understood that, in the embodiment shown in FIG. 8 or FIG. 9, first metal bus lines can also be provided to reduce the resistance of the second electrode.

The present disclosure further provides a display apparatus including the display panel described above. The display apparatus can be an AR display apparatus, or a VR display apparatus.

Since the display apparatus provided by the embodiment of the present disclosure includes the display panel described above, it has the same or corresponding technical effects as the above display panel.

The above is a detailed description of the present disclosure in connection with the specific preferred embodiments, and the specific embodiments of the present disclosure are not limited to the description. Modifications and substitutions can be made without departing from the spirit and scope of the present disclosure.

What is claimed is:

1. A display panel, comprising:
a substrate of crystalline silicon including a display area and a non-display area; a pixel circuit layer located in the display area on one side of the substrate, wherein the pixel circuit layer comprises a plurality of scan lines, a plurality of data lines and a plurality of power lines;
a pixel definition layer located on a side of the pixel circuit layer away from the substrate, wherein the pixel definition layer comprises a plurality of openings and a plurality of barriers circumferentially surrounding each opening;
a plurality of organic light-emitting elements with white light-emitting covering the display area, wherein the organic light-emitting element comprises a first electrode layer, a light-emitting function layer, and a second electrode layer that are sequentially stacked and the first electrode layer is more adjacent to the substrate;
wherein the first electrode layer comprises a plurality of independent first electrodes, the second electrode layer comprises a plurality of second electrodes, wherein each second electrode comprises at least one striped opening, and vertical projections of the striped openings on the display area overlap at least 75% of vertical projections of the scan lines on the display area.

2. The display panel according to claim 1, wherein, a width of the striped opening is greater than or equal to a width of the scan line.

3. The display panel according to claim 1, wherein, the second electrode comprises a plurality of branch electrodes, wherein a vertical projection of each branch electrode on the display area is located between the vertical projections of two adjacent scan lines on the display area.

4. The display panel according to claim 3, wherein, the pixel circuit layer further comprises a plurality of transistors and a plurality of storage capacitors, wherein vertical projections of the branch electrodes on the substrate overlap at most 10% of vertical projections of the transistors and/or the storage capacitors on the substrate.

5. The display panel according to claim 4, wherein vertical projections of the first electrodes on the substrate overlap at most 10% of vertical projections of the transistors and/or the storage capacitors on the substrate.

6. The display panel according to claim 3, wherein the branch electrodes are connected to each other in the non-display area.

7. The display panel according to claim 3, wherein the display panel further comprises a plurality of first metal bus lines, the first metal bus lines are located on a side of the second electrode layer away from the substrate, and the branch electrodes are connected to each other through the first metal bus lines.

8. The display panel according to claim 1, wherein the display panel further comprises a color resistance layer and a light-shielding layer, the color resistance layer and the light-shielding layer are located on a side of the organic light-emitting elements away from the substrate, wherein the color resistance layer overlaps the first electrode layer, and the light-shielding layer overlaps the barriers.

9. A display apparatus comprising a display panel according to claim 1.

10. The display apparatus according to claim 9, wherein a width of the striped opening is greater than or equal to a width of the scan line.

11. The display apparatus according to claim 9, wherein the second electrode comprises a plurality of branch electrodes, wherein a vertical projection of a branch electrode on the display area is located between the vertical projections of two adjacent scan lines on the display area.

12. The display apparatus according to claim 11, wherein the pixel circuit layer further comprises a plurality of transistors and a plurality of storage capacitors, wherein vertical projections of the branch electrodes on the substrate overlap at most 10% of vertical projections of the transistors and/or the storage capacitors on the substrate.

13. The display apparatus according to claim 12, wherein vertical projections of the first electrodes on the substrate overlap at most 10% of vertical projections of the transistors and/or the storage capacitors on the substrate.

14. The display apparatus according to claim 11, wherein, the branch electrodes are connected to each other in the non-display area.

15. The display apparatus according to claim 11, wherein the display panel further comprises a plurality of first metal bus lines, the first metal bus lines are located on a side of the second electrode layer away from the substrate, and the branch electrodes are connected to each other through the first metal bus lines.

16. The display apparatus according to claim 9, wherein the display panel further comprises a color resistance layer and a light-shielding layer, the color resistance layer and the light-shielding layer are located on a side of the organic light-emitting elements away from the substrate, wherein, the color resistance layer covers the first electrode layer, and the light-shielding layer covers the barriers.
